(19) United States
(12) Patent Application Publication
(10) Pub. No.: US 2002/0144397 A1
(43) Pub. Date: Oct. 10, 2002

(54) Subtractive process for fabricating cylindrical printed circuit boards

(76) Inventor: Terrel L. Morris, Garland, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 09/489,381

(22) Filed: Jan. 21, 2000

(51) Int. Cl. H01F 7/06; H05K 3/02; H05K 1/16

(52) U.S. Cl. 29/848; 29/847; 29/605; 174/260; 29/606

(57) ABSTRACT

A process for the fabrication of cylindrical circuit boards. The process is easily manufacturable since rotation of the cylindrical printed circuit board about its longitudinal axis enables automatic application of dielectric and metal layers and also allows controllable curing and etching processes. Metal layers may be constructed as planar layers or as stripline layers and both may be used in combination within a single cylindrical circuit board.

### FIELD OF THE INVENTION

This invention relates generally to the field of electronic printed circuit boards and more particularly to cylindrical printed circuit boards.

### BACKGROUND OF THE INVENTION

Planar printed circuit boards are well known in the art. However, some applications, such as construction of high-performance connectors, have density and performance requirements that currently are not well met by commercially available connectors. Many current connectors negatively impact signal propagation due to their introduction of discontinuities in conductor spacing, conductor width, and dielectric coefficient. These discontinuities result from the connector being manufactured from materials differing from those used in the printed circuit boards. Signals propagating through such a connector will be degraded by reflections caused by these discontinuities. The simultaneous requirements for robust connectivity, serviceability, and excellent electrical properties have resulted in a series of design trade-offs that delivered less than optimal signal performance, particularly in the 90-degree configurations often used to connect a backplane to a daughter card.

Many computer systems are built with a backplane/daughter board configuration. In this type of construction, the backplane may severely limit the speed of the computer. Signals travelling from one daughter board through the backplane to another daughter board are degraded by the two connectors, and the backplane itself adds delay. This delay through the backplane is dependent on the distance between the two daughter boards. The daughter board spacing is determined by the maximum height of components attached to any daughter board. Since the backplane must be built to accommodate any combination of daughter boards, the maximum possible height of components determines the minimum connector spacing on the backplane. If a cylindrical backplane were fabricated, the daughter boards would radiate out from the center cylindrical backplane. The tallest components would be attached to the outer parts of the daughter board and only very short components would be attached near the connector of the daughter board. This would allow the daughter board spacing along the surface of the cylindrical backplane to be determined by the size of the connector and not by the maximum component height. Since the distance between connectors is shortened, the delay due to the backplane is likewise shortened.

Industries such as communications or the oil industry need the capability of sending electronics down drill holes, through pipes or through other hollow cylindrical shapes for the purpose of surveying, inspecting, cleaning, or testing the pipes, holes or conduits. Using a cylindrical circuit board, it may be easier to construct the necessary circuits for any of the tasks required within a pipe or other cylindrical opening.

There is a need in the art for a manufacturing process capable of producing a circuit board with a cylindrical shape. The completed circuit board may be used as a connector, backplane, or cylindrical circuit. Manufacturability will be maximized if the process easily lends itself to automation, and if the process uses commonly available materials, technology, and process steps.

### SUMMARY OF THE INVENTION

A cylindrical circuit board is fabricated in a manner allowing use as a connector, computer backplane, or simply as a cylindrical circuit board. A unique manufacturing process allows a wide variety of designs while simultaneously allowing volume production.

Similar to a planar printed circuit board, the cylindrical circuit board may contain a large quantity of interconnecting traces, thru-holes or solder pads for placement of discrete components, and virtually any other structure possible with a planar circuit board. The cylindrical circuit board may be built around any size cylindrical core to produce cylindrical circuit boards of any diameter and length. Photolithographic processes may be used in the fabrication of these boards similar to the processes used in planar circuit board fabrication.

Many aspects of this process may be varied while still using the basic design and manufacturing process steps described. Thus the finished circuit board may be easily adapted to the specific requirements of many different applications.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1A through FIG. 1L consist of twelve process step descriptions showing one method for constructing the cylindrical printed circuit board and its use as a 90-degree connector.

FIG. 2 is a drawing of the cross-section of the finished connector assembly connecting a backplane to a daughter card.

FIG. 3 is a drawing showing one of the possible pad array patterns that can be plated on the flat side of the connector assembly.

FIG. 4A and FIG. 4B are drawings showing how pads may be selectively connected to ground layers or signal traces as required.

FIG. 5A and FIG. 5B are drawings showing how connection patterns for single-ended and differential signals may be optimized.

FIG. 6 is a drawing of a differential signal array as viewed looking into a flat side of the finished connector.

FIG. 7A through FIG. 7D are drawings showing four of the more efficient types of stripline layers that may be constructed with the cylindrical printed circuit board process.

FIG. 8A and FIG. 8B are drawings of two different types of embedded-wire constructions.

FIG. 9 is a detailed view of the cut line.

FIG. 10 is a side view of a cylindrical power/ground plane layer with cutouts in place.

### DETAILED DESCRIPTION

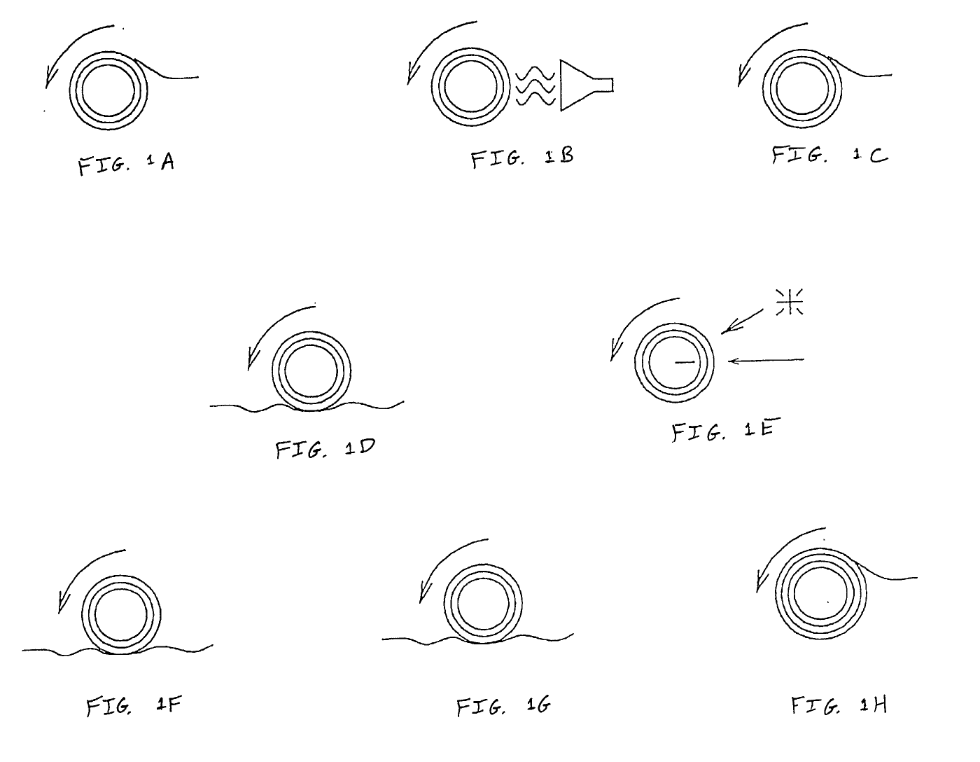

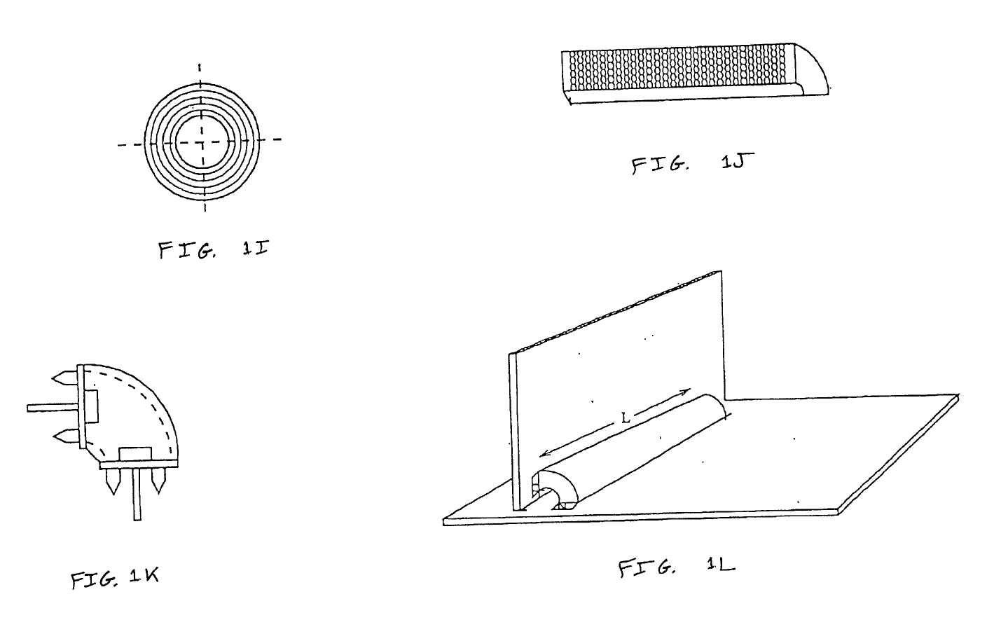

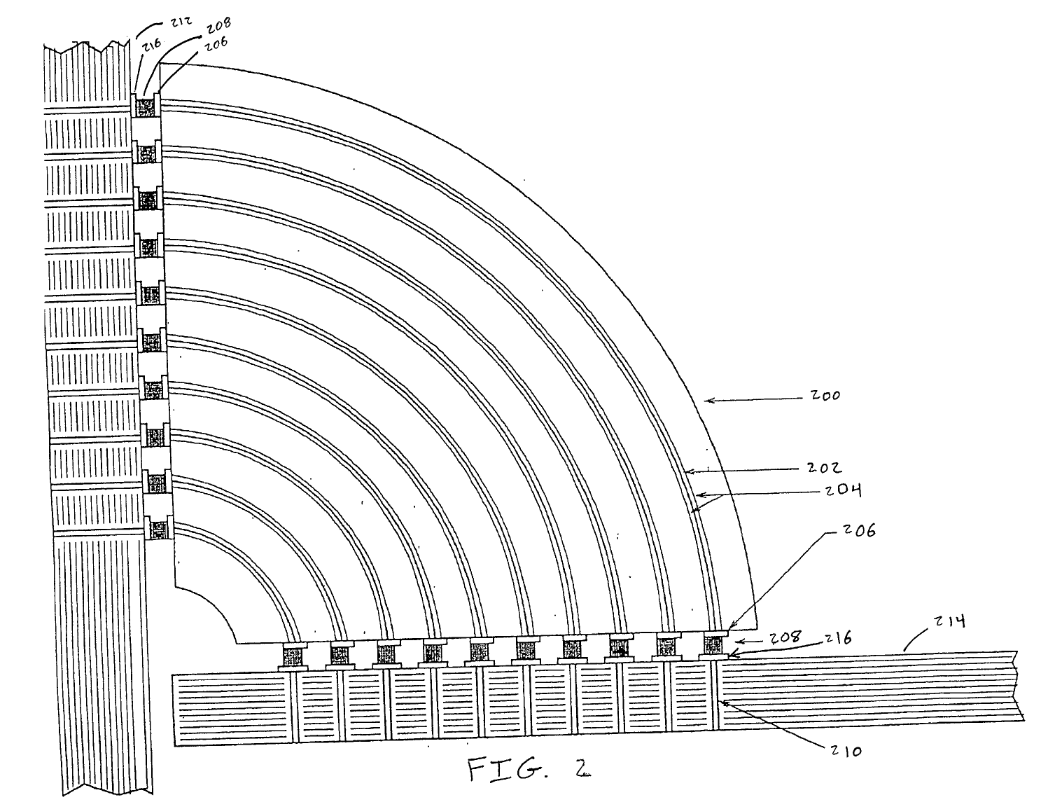

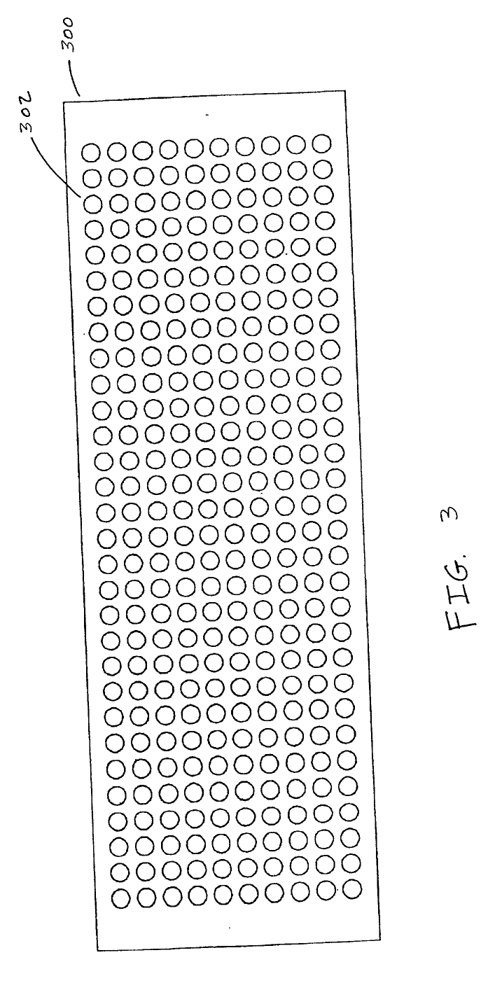

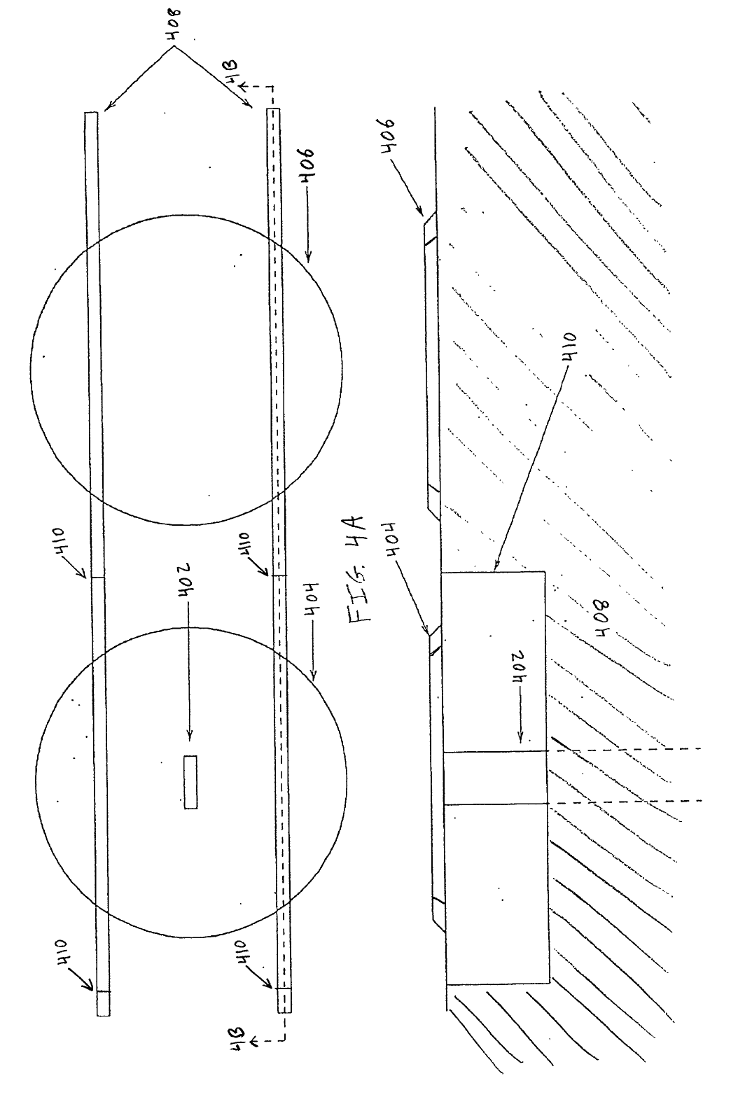

FIG. 1A through FIG. 1L consist of twelve process step descriptions showing one method for constructing the cylindrical printed circuit board and its use as a 90-degree connector. In brief, a cylinder is formed, comprising concentric layers of connecting metal, separated by concentric layers of dielectric material. A series of process steps are followed, many of them taking advantage of the fact that the cylinder may be rotated during each process step. The rotation of the cylinder about the lengthwise axis eases application of materials, curing steps, imaging, roll forming, and steps requiring immersion or partial immersion in liquids.

In FIG. 1A dielectric layers are wound around a form made of metal, glass, ceramic, plastic, or any other material deemed suitable for this application. The dielectric may be wound in individual strands, as is common in the manufacture of fishing rods and fiberglass radio antennae. It may be rolled on in sheets or layers, or it may be sprayed in place. If it is rolled on in sheets or layers, the seams may be aligned by indexing them to occur in a specific position on the cylinder. The dielectric material may be epoxy/glass, Teflon, mylar, or ceramic, or others as required by the desired application. If required, an opposing roller may be used to control thickness of the dielectric to precise dimensions.

In FIG. 1B the dielectric layers are cured as required. Ultraviolet light, infrared heat lamps, ovens or other curing processes may be applied as needed to meet the requirements of the materials.

In FIG. 1C copper (or other metal) foil is applied to form a conductive layer. This metal may be coated with adhesive and rolled in place, may be plated in place, sputtered in place, or otherwise deposited on the outside of the cylinder. Alternatively, an additive process may be used. For example, the signal traces may be made of round, flat, or oval wire, wound in place around the cylinder to form stripline conductors. This wire may be plain, or may be coated with dielectric materials and/or adhesive materials.

In FIG. 1D photo-resist material is added to the metal layer to provide a means of controlled pattern etching if a subtractive process is to be used. If the metal application process to be used is an additive process, i.e. the signal traces and ground layers are selectively applied, then this step is not needed.

In FIG. 1E the photo-resist material is imaged as required to provide proper signal trace width and location, or proper power/ground pattern images. If the metal application process to be used is an additive process, then this step is not needed.

FIG. 1F shows the etching of the metal layers as required. If the metal application process to be used is an additive process, then this step is not needed. Alternatively, if metal were deposited, plated, rolled, formed, or otherwise applied in uniform fashion to the cylinder, a mechanical cutting process or laser imaging process could be used to form individual conductors as required.

In FIG. 1G the photo-resist, if used, is stripped from the cylinder and the surface prepared for the next dielectric layer. If alternative metal processes or wire processes were used in the creation of signal traces, then the appropriate surface preparation process step is used in place of photo-resist.

FIG. 1H shows the addition of the next dielectric layer, using the same process as shown in FIG. 1A, or with appropriate process variations as required to maintain proper thickness, adhesion, or other desired properties.

In FIG. 1I the formed cylinder is sawn, cut, laser cut, or otherwise separated into quadrants. If required, the flat surfaces formed by the cutting operation may be sanded, buffed, polished or otherwise prepared for the addition of surface pads.

The surface pads are shown in FIG. 1J. These pads may be imaged and plated, as in standard PCB processes, or alternatively sputtered, formed, or welded in place. Pads may then be plated with the desired surface finish, including, but not limited to gold, palladium/nickel, tin/lead, or tin/antimony. In place of separate pads, the interposer connection array may be directly welded, plated, or otherwise conductively attached to the signal traces and ground planes exposed on the flat surface of the conductor.

FIG. 1K shows the end plates or other hardware that is added to permit accurate location of the connector assembly to the PCB, and to permit retention of the connector and daughter card to the backplane. Note that the connector may alternatively be bolted to the daughter card, and held in place to the backplane by card cage mechanical features such as levers, cams, thumbscrews or other devices. The connector may also be constructed such that it has ball grid array (BGA) solder balls, solder columns, or solder paste applied to the pads at the daughter card interface, and it may be reflow soldered for a semi-permanent attachment to the daughter card.

FIG. 1L illustrates that the connector length, number of layers, and other physical form factors may be adjusted as needed by each potential application, or a series of standard shapes and sizes may be developed.

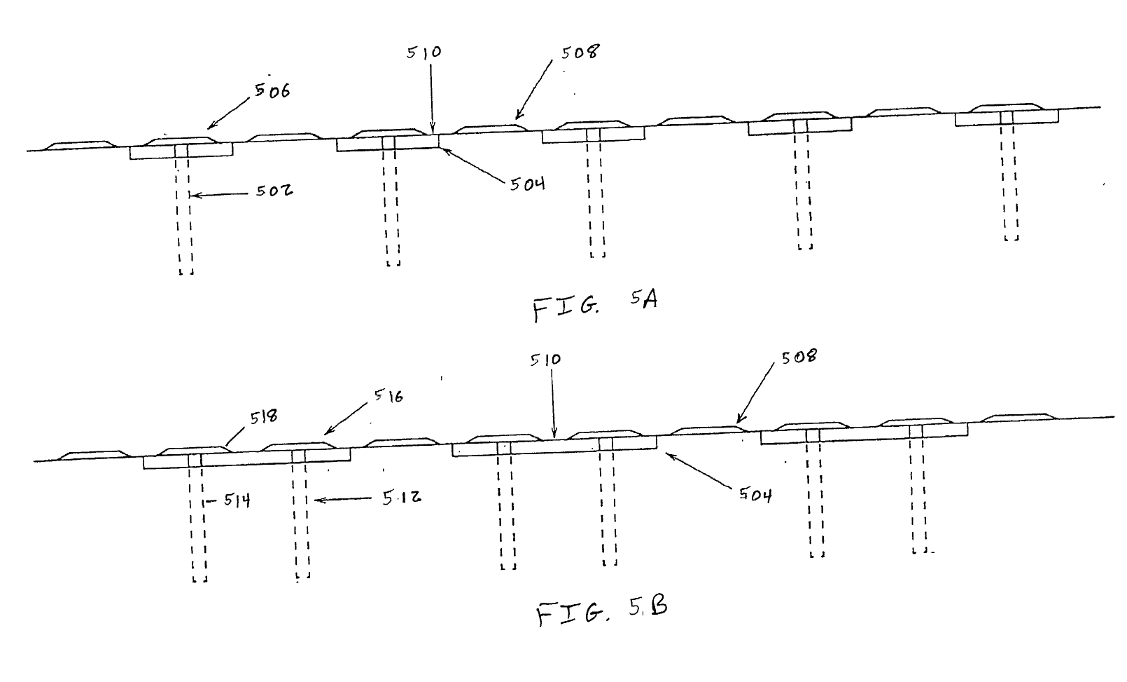

FIG. 2 is a drawing of the cross-section of the finished connector assembly 200 connecting a backplane to a daughter card. In this embodiment of the invention, the laminated connector board has been constructed in a printed circuit board type of process around a cylindrical core. This printed circuit board cylinder was then sectioned along the lengthwise axis into quadrants forming four 90-degree laminated connector boards. An example of the type of process used to build this cylindrical printed circuit board is shown in FIG. 1A through FIG. 1L and described above. The connector assembly 200 connects a backplane 212 to a daughter card 214. The connector assembly 200 features plated pads 206, that use an array of elastomeric, stamped, or fuzz-button interposer contacts, or solder balls 208 to connect to PCB pads 216 and vias 210. The plated pads 206 are formed on the edges of the board where the cylinder was cut into quarters. Signal conductors 202 are surrounded by ground planes 204, using spacing and dielectric materials common to PCBs. The signal conductors 202 and ground planes 204 are designed such that only one signal reaches the cut lines of the cylinder so that when the plated pads 206 are formed there are no electrical shorts between adjacent traces. Thus each signal layer may be completely shielded from each adjacent layer. The length of the connectors may be set by the desired number of signal/power/ground traces that need to be connected between the backplane 212 and a daughter card 214. Since signals propagate in the same conductor materials as the PCB, and are surrounded by the same dielectrics as used in a PCB, they travel at the same velocity, and in the same mode of propagation as signals within the PCB.

FIG. 3 is a drawing showing one of the possible pad array patterns that can be plated on the flat side of the connector assembly 300. Note that the pad shape, distance between pads on vertical or horizontal axes, pad material, and plated coatings may be varied as required by the system application. Also, the number of pads may be varied as required.

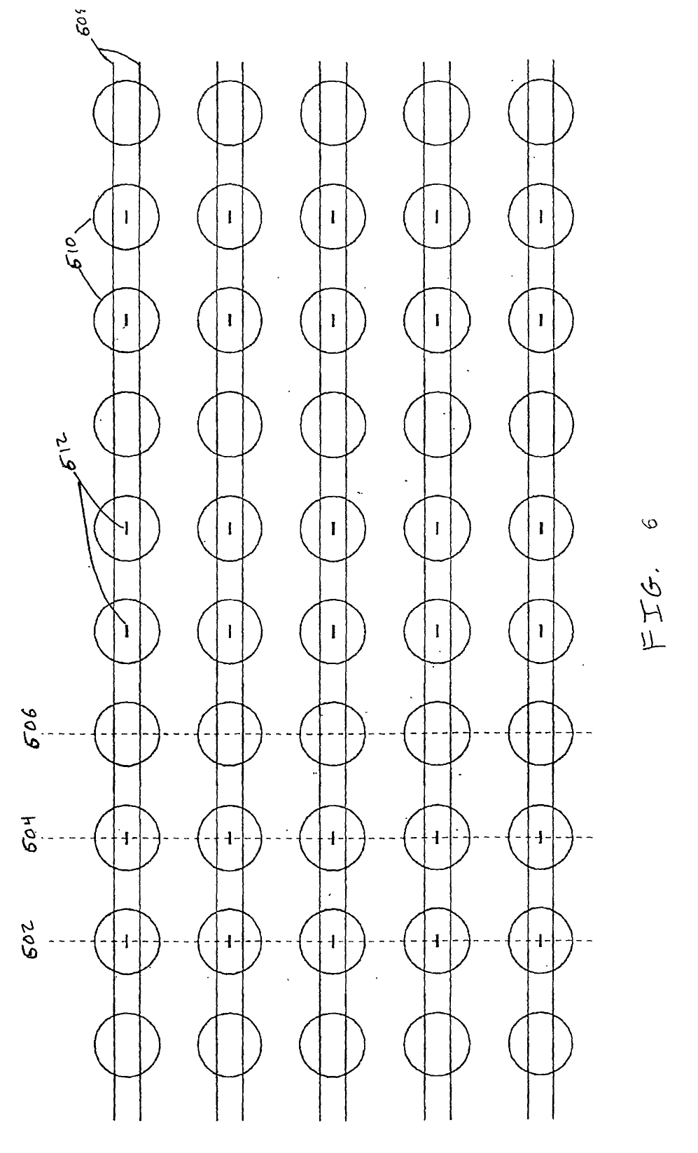

FIG. 4A and FIG. 4B are drawings showing how pads may be selectively connected to ground layers or signal traces as required. FIG. 4A is a top view showing how signal trace 402 is connected to pad 404, but isolated from ground layers 408. In FIG. 4A, pad 406 is connected to ground layers 408, providing a low-impedance ground connection to the PCB. In the cross section, FIG. 4B, the connection between signal trace 402 and pad 404 is shown, as well as the isolation from ground layers 410. Note the cut 410 in the ground layer 408 around the signal pad 404. FIG. 10, described in detail below, is a representation of one possible ground plane design. The plurality of cut outs, 1002 and 1004, in the ground plane may be seen in FIG. 10. This keeps the ground layer 408 from shorting to the signal trace 402 through the signal pad 404. The connection between pad 406 and ground layers 408 is also shown. It may be desirable to limit the ground plane layers to protrude to the surface only in areas directly under the pads, so that no ground plane materials are exposed in areas not covered by pads. Alternatively, one ground plane layer of the pair may be assigned to power, creating a power-signal-ground stackup. The example shown uses 4 mil wide signal lines and 24 mil diameter pads on a 40 mil pitch, however many combinations of signal and pad geometries are possible using the techniques described in this document.

FIG. 5A and FIG. 5B are drawings showing how connection patterns for single-ended and differential signals may be optimized. Selective connections between pads and signals or pads and power/ground layers may be used to create structures that are ideal for certain types of signal propagation. Signal trace 502 is connected to pad 506, that is plated onto the flat surface of the connector body 510, but not connected to power/ground layers 504. Pad 508 is connected to power/ground layers 504, but not to the signal trace 502. In this pattern, signal pads 506 alternate with ground pads 508. Utilization of the pattern shown allows a 1:1 signal to ground ratio at the pad array and in the PCB vias, optimizing single-ended performance.

Likewise, FIG. 5B shows a differential pattern that has been optimized for true-complement pairs of signals. In this case, the pair of signal traces 512 and 514 are connected to pads 516 and 518, that are plated onto the flat surface of the connector body 510, but not connected to power/ground layers 504. Pad 508 is connected to power/ground layers 504, but not to the signal traces 512 and 514. In this pattern, groups of two signal pads 516 and 518 alternate with ground pads 508. Since two adjacent pads are used for signal traces, true-complement coupling is optimized within a signal pair, but the ground connections between pairs prevent excessive pair-to-pair coupling.

Using the basic techniques shown in FIG. 5A and FIG. 5B, many combinations of pad, signal, power, and ground combinations may be utilized to ensure optimal interconnect performance for many different signaling applications.

FIG. 6 is a drawing of a differential signal array as viewed looking into a flat side of the finished connector. An array of signals 612 sandwiched between power/ground planes 608 are connected to an array of circular pads 610. Signal column 602 is comprised of “true” signals, signal column 604 is comprised of “complement” signals, and the true-complement pairs are surrounded by power/ground columns 606. Note that this configuration is only one of many possible signal configurations. Staggered, inter-digitated, and offset patterns are also possible. Pad shape may also be oval, “dogbone”, square, or any other shape as dictated by connectivity optimization, capacitance minimization, and design rules.

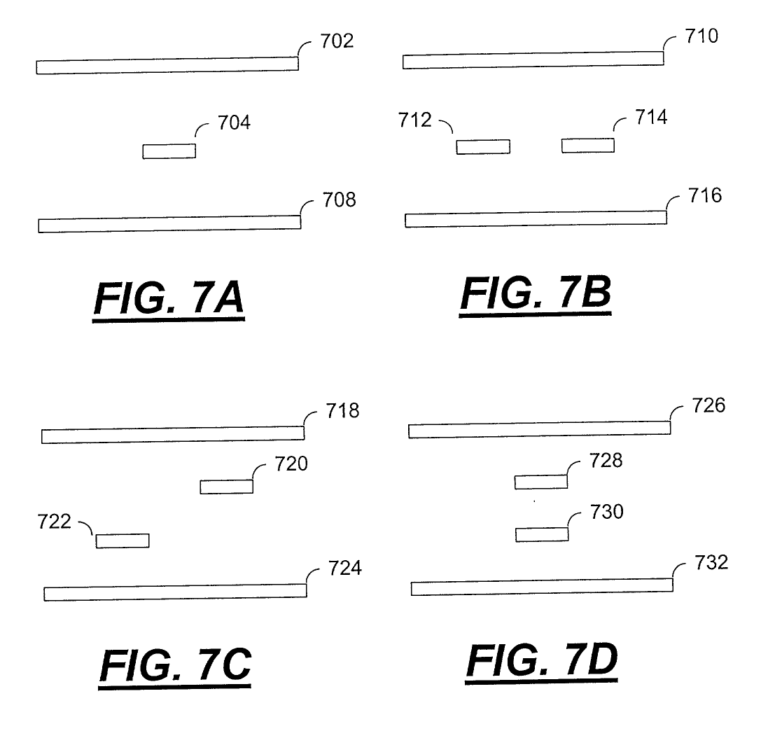

FIG. 7A through FIG. 7D are drawings showing four of the more efficient types of stripline layers that may be constructed with the cylindrical printed circuit board process. Generally, any structure that may be created in a planar PCB may be created in the cylindrical PCB process for use in a connector.

The stripline shown in FIG. 7A is a single conductor 704 sandwiched between two power/ground planes 702 and 708.

FIG. 7B shows a dual conductor stripline such as for a differential signal, with the two signal traces 712 and 714 sandwiched between two power/ground planes 710 and 716.

FIG. 7C also shows a dual conductor stripline such as for a differential signal, where the two signal traces 720 and 722 are horizontally offset and also on different conducting layers sandwiched between two power/ground planes 718 and 724.

FIG. 7D also shows a dual conductor stripline such as for a differential signal, where the two signal traces 728 and 738 are on different conducting layers sandwiched between two power/ground planes 726 and 732.

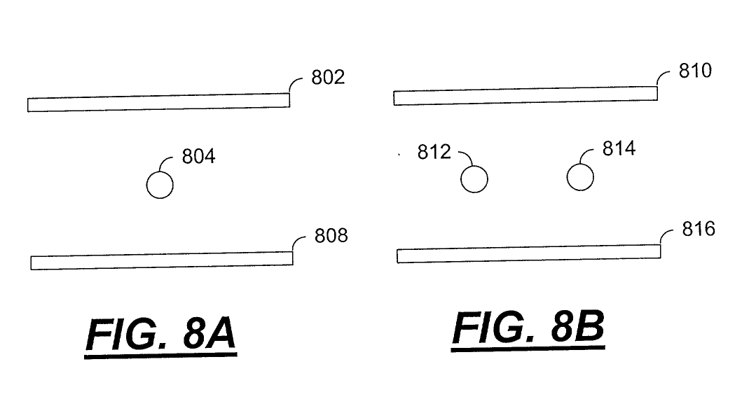

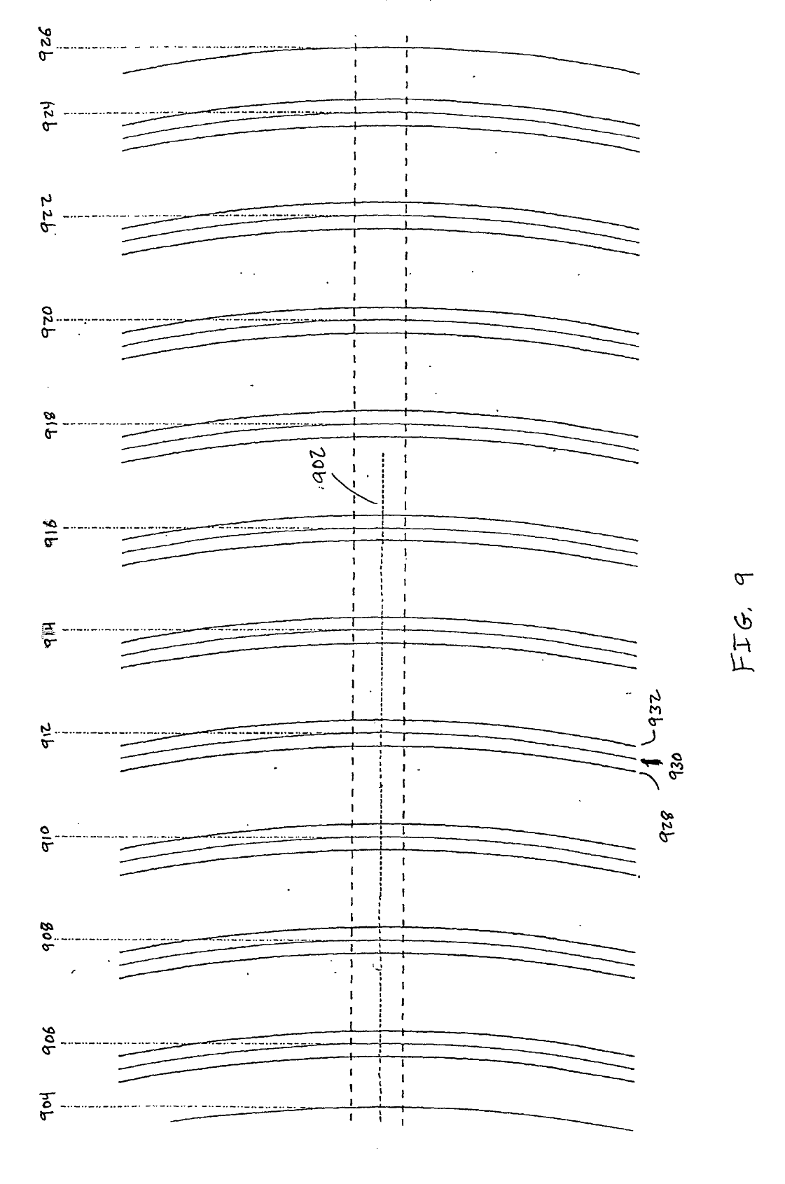

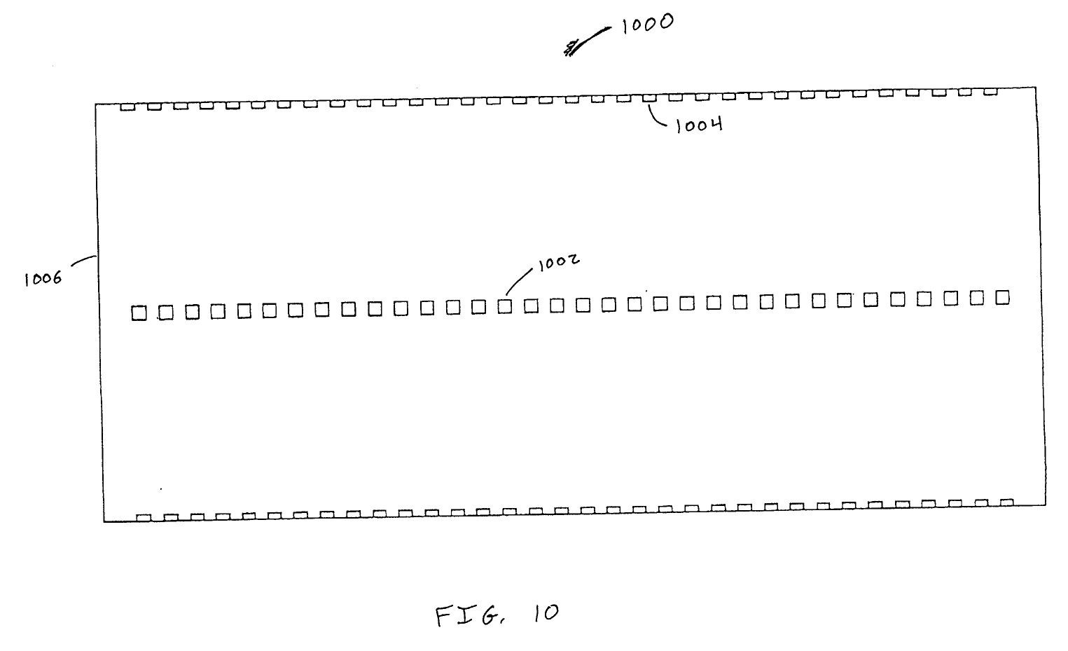

FIG. 8A and FIG. 8B are drawings of two different types of embedded-wire constructions. Other constructions using embedded wires are also possible.

FIG. 8A shows a single conductor 804 sandwiched between two power/ground planes 802 and 808. FIG. 8B shows a dual conductor such as for a differential signal with two signal wires 812 and 814 sandwiched between two power/ground planes 810 and 816.

FIG. 9 shows a detailed view of the cut line 902 axially through a cylindrical printed circuit board, and the layers formed by the various process steps. Dimensions are given for the case with signals on a 40-mil (1.016 millimeters) grid. Other spacings are possible. In the 40-mil (1.016 millimeters) grid example, point 904 is the edge at 0.0 millimeters. Point 906 is at 0.635 millimeters. Point 908 is at 1.651 millimeters. Point 910 is at 2.667 millimeters. Point 912 is at 3.683 millimeters. Point 914 is at 4.699 millimeters. Point 916 is at 5.715 millimeters. Point 918 is at 6.731 millimeters. Point 920 is at 7.747 millimeters. Point 922 is at 8.763 millimeters. Point 924 is at 9.779 millimeters. The other edge 926 is at 10.414 millimeters. Each of the signal traces 930 is sandwiched between two power/ground planes 928 and 932.

FIG. 10 shows a side view 1000 of a cylindrical power/ground plane 1006 with square cutouts 1002 and 1004 in place. The cutouts 1002 and 1004 enable selective attachments to power/ground as shown in FIG. 4. Each cutout 1002 and 1004 represents a location where a signal trace will connect to a pad.

Another embodiment of this invention may build a cylindrical printed circuit board from the inside out, rather than rolling on a center core form. In this case, the form would be a hollow cylinder that would rotate about the center axis. Sprayed, rolled, or slurried materials could be precisely deposited in this fashion. Stepper motor control, combined with accurate spray or other deposition methods may be employed to precisely deposit dielectrics and conductors as required to build the shapes needed.

Another embodiment of this invention is a process for constructing the embedded wire striplines shown in FIG. 8 that involves winding a continuous spiral of wire about a rotating cylindrical core. The pads may be offset a small amount to make up for the positional variations induced by the spiral. When the cylinder is cut for use as a connector, the wire ends are available for forming pads by a plating process. If the cylindrical printed circuit board is designed for uses other than as a connector, the spiral of wire may be cut as needed to form stripline conductors within the circuit board. Once again, stepper motor control may be used to precisely rotate the cylindrical printed circuit board under a cutting head for accurate cutting of the spiral of wire. This stripline process may be combined with planar conductor processes to form ground and power planes surrounding the stripline conductors.

The foregoing description of the present invention has been presented for purposes of illustration and description. It is not intended to be exhaustive or to limit the invention to the precise form disclosed, and other modifications and variations may be possible in light of the above teachings. The embodiments were chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A process for the fabrication of circuit boards comprising:
applying a dielectric layer over a substantially cylindrical form;
curing said dielectric layer;
applying a metal layer over said dielectric layer;
forming conductors from said metal layer.

2. The process for the fabrication of circuit boards as recited in claim 1 wherein the step of forming conductors from said first metal layer comprises:
applying a photo-resist layer over said metal layer;
imaging said photo-resist layer;
etching said metal layer;
stripping said photo-resist layer.

3. The process for the fabrication of circuit boards as recited in claim 2 further comprising:
adding additional dielectric and metal layers using a process comprising the following steps for each additional dielectric and metal layer:
applying an additional dielectric layer;
curing said additional dielectric layer;
applying an additional metal layer over said additional dielectric layer;
applying an additional photo-resist layer over said additional metal layer;
imaging said additional photo-resist layer;
etching said additional metal layer;
stripping said additional photo-resist layer.

4. The process for the fabrication of circuit boards as recited in claim 3 wherein at least one of said metal layers consist of metal foil.

5. A process for the fabrication of circuit boards comprising:
applying at least one dielectric layer to a substantially cylindrical form;
forming at least one conductor between said dielectric layers.

6. The process for the fabrication of circuit boards as recited in claim 5 further comprising:
curing said dielectric layers.

7. The process for the fabrication of circuit boards as recited in claim 5 wherein said forming at least one conductor step further comprises:
wrapping said cylindrical form with a spiral of wire;
adhering said wire to said cylindrical form; and
cutting said wire to form at least one conductor.

8. A circuit board comprising:
at least one dielectric layer;
at least one conductive layer;
at least one site for attachment of components;
wherein said dielectric layers and said conductive layers are substantially cylindrical in shape.

9. The circuit board as recited in claim 8 further comprising:
at least one power supply plane.

10. The circuit board as recited in claim 8 wherein said conductive layer comprises at least one conductor.

11. The circuit board as recited in claim 10 where in said conductors are stripline.
